(19) United States
(12) Patent Application Publication
(10) Pub. No.: US 2025/0169342 A1
(43) Pub. Date: May 22, 2025

(54) DISPLAY DEVICE AND MOBILE ELECTRONIC DEVICE INCLUDING SAME

(71) Applicant: Samsung Display Co., LTD., Yongin-si (KR)

(72) Inventors: Bo Ock JANG, Yongin-si (KR); Sae Bom DO, Yongin-si (KR); Soo Ran PARK, Yongin-si (KR)

(21) Appl. No.: 18/928,360

(22) Filed: Oct. 28, 2024

(30) Foreign Application Priority Data
Nov. 20, 2023 (KR) 10-2023-0160335

(51) Int. Cl. H10K 59/95; G06F 3/041; G06F 3/044; H01L 27/08; H10K 59/40; H10K 102/00

(52) U.S. Cl. CPC H10K 59/95; H10K 59/40; G06F 3/0412; G06F 3/0446; G06F 2203/04102; H10D 84/212; H10K 2102/311

(57) ABSTRACT

A display device includes a display panel including a main area including a display area and a non-display area, and a sub-area extending from one side of the main area, and a circuit board connected to the sub-area and including a charge pump capacitor. Around the charge pump capacitor, a first cover layer of the circuit board is removed and an opening exposing a ground line disposed below the first cover layer is disposed.

This application claims priority to Korean Patent Application No. 10-2023-0160335, filed on Nov. 20, 2023, and all the benefits accruing therefrom under 35 U.S.C. § 119, the content of which in its entirety is herein incorporated by reference.

### BACKGROUND

### 1. Field

The present invention relates to a display device, and particularly to a display device and a mobile electronic device including the same.

### 2. Description of the Related Art

As the information-oriented society evolves, various demands for display devices are ever increasing. The display device may be a flat panel display device such as a liquid crystal display, a field emission display and a light emitting display. Light-emitting display devices may include an organic light-emitting display device including organic light-emitting emitting diodes as light-emitting elements, or a light-emitting diode display device including inorganic light-emitting diodes such as light-emitting diodes (LEDs) as light-emitting elements.

The display device may include a touch panel as an input device and a touch driving circuit for driving the touch panel which generates a touch driving signal for driving touch electrodes of the touch panel.

### SUMMARY

Aspects of the invention provide a display device capable of preventing damage to components due to static electricity generated around a charge pump and a mobile electronic device including the same.

According to an embodiment, a display device may include a display panel including a main area including a display area and a non-display area, and a sub-area extending from one side of the main area, and a circuit board connected to the sub-area and including a charge pump capacitor. Around the charge pump capacitor, a first cover layer of the circuit board is removed and an opening exposing a ground line disposed below the first cover layer is disposed.

In an embodiment, a stacked structure of the circuit board includes the first cover layer, a first metal layer disposed below the first cover layer and including the ground line, a first insulating layer disposed below the first metal layer, a second metal layer disposed below the first insulating layer, and a second cover layer disposed below the second metal layer.

In an embodiment, the circuit board is a flexible printed circuit board.

In an embodiment, the opening is disposed to surround the charge pump capacitor.

In an embodiment, each of the openings have a quadrilateral shape when viewed from the top.

In an embodiment, each of the openings have a circular shape when viewed from the top.

In an embodiment, the circuit board includes a stabilization capacitor connected between a regulator element and the ground line, where the stabilization capacitor is connected to the ground line and includes a ground electrode disposed to face the charge pump capacitor.

In an embodiment, the stabilization capacitor and the charge pump capacitor are disposed within a specified distance.

In an embodiment, the stabilization capacitor is disposed to surround the charge pump capacitor.

In an embodiment, the regulator element is a low dropout (LDO).

According to an embodiment, a mobile electronic device may include a display panel including a main area including a display area and a non-display area, and a sub-area extending from one side of the main area, and a circuit board connected to the sub-area and including a charge pump capacitor, wherein, around the charge pump capacitor, a first cover layer of the circuit board is removed and an opening exposing a ground line disposed below the first cover layer is disposed.

In an embodiment, a stacked structure of the circuit board comprises the first cover layer, a first metal layer disposed below the first cover layer and including the ground line, a first insulating layer disposed below the first metal layer, a second metal layer disposed below the first insulating layer, and a second cover layer disposed below the second metal layer.

In an embodiment, the circuit board is a flexible printed circuit board.

In an embodiment, the opening is disposed to surround the charge pump capacitor.

In an embodiment, each of the openings have a quadrilateral shape when viewed from the top.

In an embodiment, each of the openings have a circular shape when viewed from the top.

In an embodiment, the circuit board includes a stabilization capacitor connected between a regulator element and the ground line, where the stabilization capacitor is connected to the ground line and includes a ground electrode disposed to face the charge pump capacitor.

In an embodiment, the stabilization capacitor and the charge pump capacitor are disposed within a specified distance.

In an embodiment, the stabilization capacitor is disposed to surround the charge pump capacitor.

In an embodiment, the regulator element is a low dropout (LDO).

According to an embodiment, damage to components can be prevented by discharging static electricity generated around a charge pump capacitor to a ground line of a circuit board.

### BRIEF DESCRIPTION OF THE DRAWINGS

The above and other aspects and features of the invention will become more apparent by describing in detail exemplary embodiments thereof with reference to the attached drawings, in which:

FIG. 1 is a schematic perspective view of a display device, according to an embodiment;

FIG. 2 is a schematic cross-sectional view of a display device, according to an embodiment;

FIG. 3 is a block diagram of a display unit and a touch driver, according to an embodiment;

FIG. 4 is a schematic plan view illustrating a display unit of a display device, according to an embodiment;

FIG. 5 is a plan view illustrating a touch unit of a display device, according to an embodiment;

FIG. 6 is an enlarged view of area A1 of the display unit of the display device of FIG. 5, according to an embodiment;

FIG. 7 is an enlarged view of a portion of a display device, according to an embodiment;

FIG. 8 is a cross-sectional view of the display device taken along line I-I′ of FIG. 7, according to an embodiment;

FIG. 9 is a block diagram schematically illustrating compartments of a touch unit and a touch driver, according to an embodiment;

FIG. 10 is a block diagram schematically illustrating a connection portion of a circuit board and a display panel, according to an embodiment;

FIG. 11 is a cross-sectional view of a circuit board, according to an embodiment;

FIG. 12 is a cross-sectional view of a portion of a circuit board showing an opening of a first cover layer, according to an embodiment;

FIG. 13 is a diagram schematically illustrating a connection portion of a circuit board and a display panel, according to an embodiment;

FIG. 14 is a plan view of a circuit board for explaining an arrangement of a stabilization capacitor and a charge pump capacitor, according to an embodiment;

FIG. 15 is a cross-sectional view of a portion of a circuit board illustrating a ground electrode of a stabilization capacitor, according to an embodiment;

FIG. 16 is an equivalent circuit diagram of a stabilization capacitor, according to an embodiment; and

FIG. 17 is an equivalent circuit diagram of a charge pump capacitor, according to an embodiment.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being disposed “on,” “connected to,” or “coupled to” another element, layer or substrate, it can be directly on the other element, layer or substrate, or intervening layers may also be present. The same reference numbers indicate the same components throughout the specification. In the attached figures, the thickness of layers and regions is exaggerated for clarity. To this end, the term “connected” may refer to physical, electrical, and/or fluid connection, with or without intervening elements.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

Features of each of various embodiments of the invention may be partially or entirely combined with each other and may technically variously interwork with each other, and respective embodiments may be implemented independently of each other or may be implemented together in association with each other.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the invention. Further, the blocks, units, parts, and/or modules of some embodiments may be physically combined into more complex blocks, units, parts, and/or modules without departing from the scope of the invention.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, specific embodiments will be described with reference to the accompanying drawings.

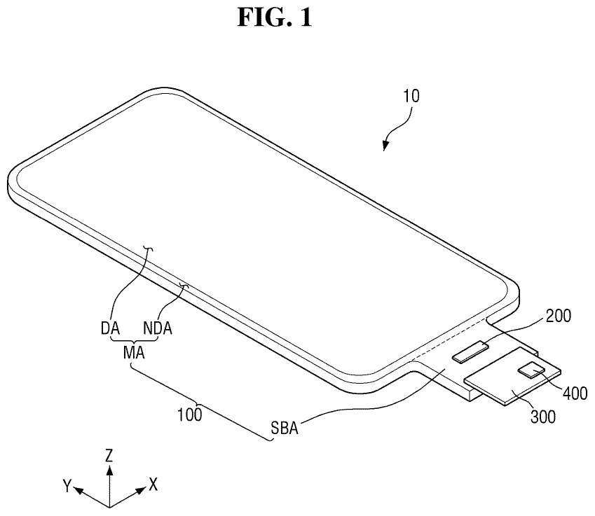

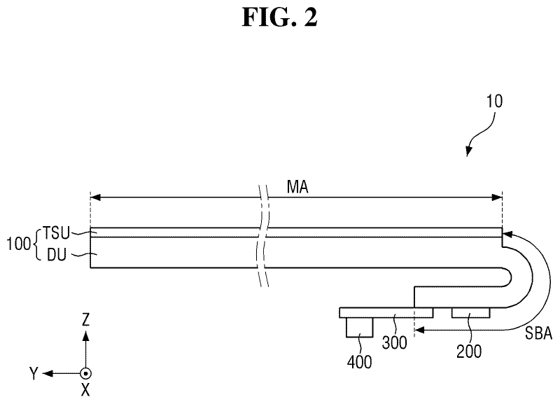

FIG. 1 is a schematic perspective view of a display device, according to an embodiment. FIG. 2 is a schematic cross-sectional view of a display device, according to an embodiment.

In the drawings, a first direction X refers to a direction parallel to a side of the display device 10 when viewed from the top, i.e., the shorter side direction of the display device 10. A second direction Y refers to a direction parallel to another side of the display device 10 that meets the side when viewed from the top, i.e., the longer side direction of the display device 10. A third direction Z refers to the thickness direction of the display device 10. It should be understood that the directions referred to in the exemplary embodiments are relative directions, and the invention is not limited to the directions mentioned.

In an embodiment, the display device 10 may include a variety of electronic devices that provide a display screen. For example, the display device 10 may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). In an embodiment, the display device 10 may be used as a display unit DU of a television, a laptop computer, a monitor, an electronic billboard, or the internet of Things (IOT). In other embodiments, the display device 10 may be applied to wearable devices such as a smart watch, a watch phone, a glasses-type display, and a head-mounted display (HMD) device.

In an embodiment and referring to FIG. 1, the display device 10 may have a shape similar to a rectangle when viewed from the top. For example, the display device 10 may have a shape similar to a quadrangle having shorter sides in the first direction X and longer sides in the second direction Y when viewed from the top. The corners where the shorter sides in the first direction X meet the longer sides in the second direction Y may be rounded with a predetermined curvature or may be a right angle. The shape of the display device 10 when viewed from the top is not limited to a rectangular shape, but may have a shape similar to other polygonal shapes, a circular shape, or an elliptical shape.

In an embodiment, at least one of the front surface and the rear surface of the display device 10 may be a display surface. As used herein, the front surface refers to the surface located on one side of a plane, i.e., the surface located on the side indicated by the arrow of the third direction Z in the drawings. The rear surface refers to the surface located on the opposite side of the plane, i.e., the surface located on the opposite side to the side indicated by the arrow of the third direction Z in the drawings. The display device 10 may be a double-sided display device 10 in which images can be displayed on both the front and rear surfaces. In the following description, the display surface is located on the front side of the display device 10, according to an embodiment.

In an embodiment, the display device 10 includes a display panel 100 providing a display screen, a display driving circuit 200, a circuit board 300 and a touch driving circuit 400. The touch driving circuit 400 is a component configured to sense a user's touch input and may be referred to as a “touch detection device.”

In an embodiment, the display panel 100 may have a shape similarly to a rectangular shape when viewed from the top. For example, the display panel 100 may have a shape similar to a quadrangle having shorter sides in the first direction X and longer sides in the second direction Y when viewed from the top. The corners where the shorter sides in the first direction X meet the longer sides in the second direction Y may be rounded with a predetermined curvature or may be a right angle. The shape of the display panel 100 when viewed from the top is not limited to a rectangular shape, but may have a shape similar to other polygonal shapes, a circular shape, or an elliptical shape. In addition, the display panel 100 may be formed to be flexible so that it can be curved or bent.

In an embodiment, the display panel 100 may include a main area MA and a sub-area SBA.

In an embodiment, the main area MA may include a display area DA including pixels for displaying images, and a non-display area NDA located around the display area DA. The display area DA may output lights from a plurality of emission areas or a plurality of open areas. For example, in an embodiment, the display panel 100 may include a pixel circuit including switching elements, a pixel-defining layer that defines the emission areas or the opening areas, and a self-light-emitting element.

In an embodiment, the non-display area NDA may be disposed on the outer side of the display area DA. The non-display area NDA may be defined as the edge of the main area MA of the display panel 100. The non-display area NDA may include a gate driver (not shown) supplying gate signals to gate lines (not shown) of the display panel 100.

In an embodiment, the sub-area SBA may extend from one side of the main area MA. The sub-area SBA may be bent such that it overlaps with the main area MA in the third direction Z. The sub-area SBA may include pads connected to the display driving circuit 200 and the circuit board 300.

In an embodiment and referring to FIG. 2, the display panel 100 may include a display unit DU and a touch unit TSU.

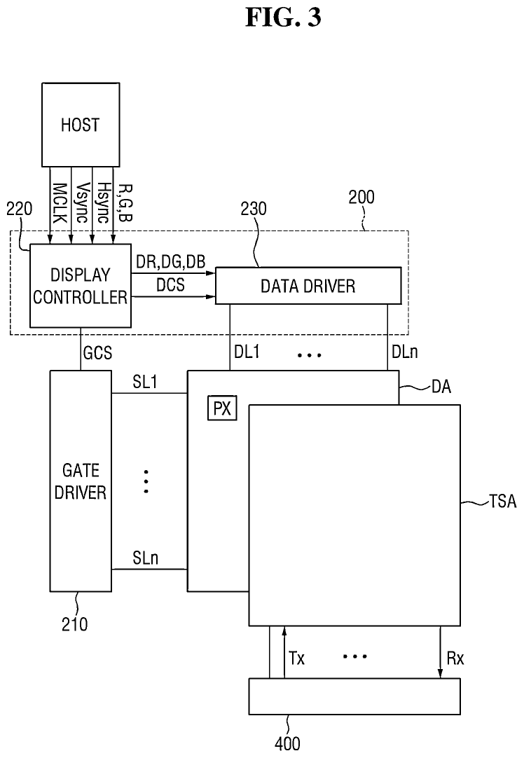

In an embodiment, the display unit DU may include a plurality of pixels PX (see FIG. 3), where each of the pixels PX is a unit for displaying an image. One pixel PX may include, but is not limited to, a red sub-pixel, a green sub-pixel and a blue sub-pixel. The plurality of pixels PX may be arranged alternately when viewed from the top. For example, the pixels PX may be arranged in, but is not limited to, a matrix.

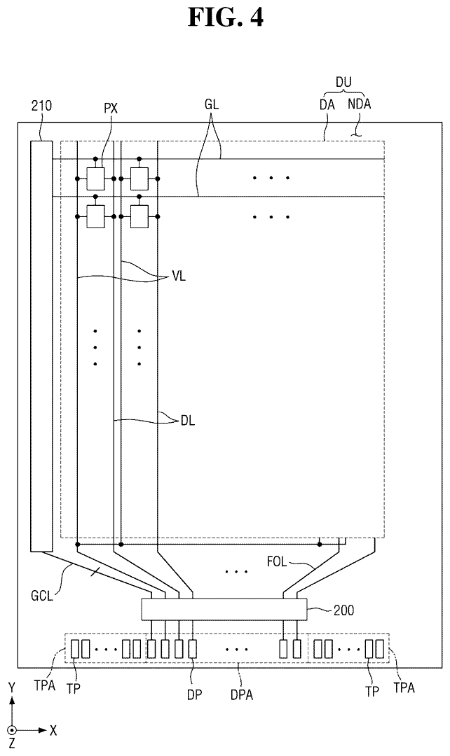

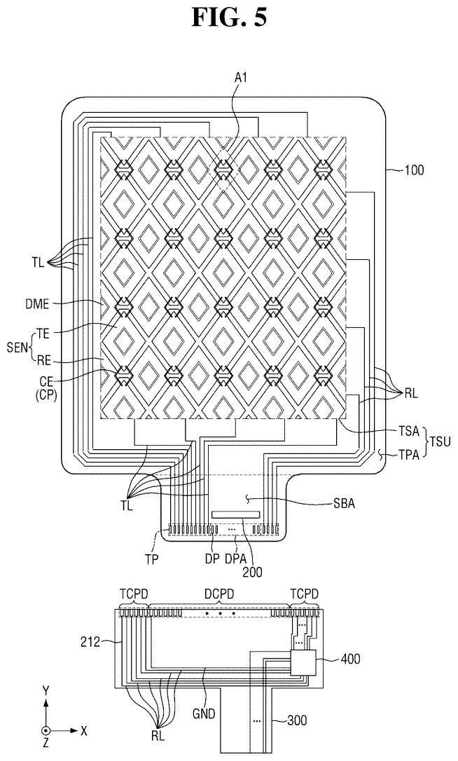

In an embodiment, the touch unit TSU may be disposed on the display unit DU, but the invention is not limited thereto. For example, in an embodiment, the touch unit TSU may be formed together with the display unit DU using an in-cell touch technology. The touch unit TSU may include a plurality of touch electrodes SEN (see FIG. 5) for detecting a user's touch by capacitive sensing, a plurality of touch driving lines TL (see FIG. 5) for connecting the plurality of touch electrodes SEN with the touch driving circuit 400, and a plurality of touch sensing lines RL (see FIG. 5). The touch unit TSU is a layer that detects a touch input and may work as a touch member. The touch unit TSU may determine whether there is a touch input and may calculate touch input coordinates of the position, if any. The display unit DU and the touch unit TSU will be described in detail later with reference to FIGS. 4 to 7.

In an embodiment, the display unit DU and the touch unit TSU may overlap each other. For example, the display area DA may display images on the screen and may detect a touch input.

In an embodiment, the sub-area SBA of the display panel 100 may extend from one side of the main area MA. The sub-area SBA may include a flexible material that can be bent, folded, or rolled. For example, a part of the sub-area SBA may be bent on one side of the main area MA, and another part of the sub-area SBA extended from the bent part of the sub-area SBA may overlap with the main area MA in the third direction (z-axis direction). The sub-area SBA may include pads connected to the display driving circuit 200 and the circuit board 300.

In an embodiment and referring to FIG. 1, the display driving circuit 200 may be disposed in the sub-area SBA of the display panel 100. In addition, the display driving circuit 200 may be implemented as an integrated circuit (IC) and may be mounted on the display panel 100 by the chip-on-glass (COG) technique, or the chip-on-plastic (COP) technique.

In an embodiment, the display driving circuit 200 may output data signals and voltages for driving the display panel 100. The display driving circuit 200 may supply data voltages to data lines (not shown) of the display panel 100. The display driving circuit 200 may provide supply power voltages to power lines of the display panel 100 and may provide gate control signals to the gate driver.

In an embodiment, the circuit board 300 may be disposed in the sub-area SBA of the display panel 100. Lead lines (not shown) of the circuit board 300 may be electrically connected to the pad area of the display panel 100. The circuit board 300 may be a flexible printed circuit board, a printed circuit board, or a flexible film such as a chip-on film.

In an embodiment, the circuit board 300 may include a plurality of conductive lines (not shown) that transmits a signal from a main circuit board (not shown) to the display driving circuit 200 or electrically connects the touch driving circuit 400 with the plurality of first electrodes TE and the plurality of second electrodes RE of the touch unit TSU.

In an embodiment, the first electrode TE (See FIG. 5) may be herein referred to as a term such as a “touch driving electrode”. The second electrode RE (See FIG. 5) y be herein referred to as a term such as a “touch sensing electrode”.

In an embodiment, the touch driving circuit 400 may be disposed in the sub-area SBA of the display panel 100. In another embodiment, the touch driving circuit 400 may be packaged on the circuit board 300.

In an embodiment, the touch driving circuit 400 may calculate whether a touch is being input and the touch coordinates, based on what amount of change in capacitance between the plurality of touch electrodes is sensed. The touch driving circuit 400 may be formed of an integrated circuit (IC), and may be packaged on the display panel 100 in a chip on plastic (COP) manner or a chip on glass (COG) manner.

FIG. 3 is a conceptual diagram of a display unit and a touch driver, according to an embodiment. FIG. 4 is a schematic plan view illustrating a display unit of a display device, according to an embodiment.

In an embodiment and referring to FIGS. 3 and 4, the display device 10 includes a display panel 100 including a plurality of pixels PX, a display driving circuit 200 and a touch driving circuit 400. The display driving circuit 200 and the touch driving circuit 400 may operate based on a control signal or a command signal from a host. For example, in an embodiment, the host may be a processor. According to an embodiment, the touch driving circuit 400 may be controlled by the display driving circuit 200.

In an embodiment, the display driving circuit 200 may include a data driver 230 and a display controller 220.

In an embodiment, the display controller 220 may receive input data R, G and B and a timing control signal from the outside (e.g., host). The timing control signal may include a vertical synchronization signal Vsync indicating one frame period, a horizontal synchronization signal Hsync indicating one horizontal period and a main clock MCLK repeated at a predetermined cycle. The input data R, G and B may be RGB data including red image data, green image data and blue image data. The display controller 220 may generate output data signals DR, DG and DB and an internal control signal by using the received input data R, G and B and the timing control signal. The internal control signal includes a data control signal DCS and a gate control signal GCS.

In an embodiment, the display controller 220 may control the operation of the data driver 230 by providing the data control signal DCS to the data driver 230. The display controller 220 may control the operation of the gate driver 210 by providing the gate control signal GCS to the gate driver 210.

In an embodiment, the data driver 230 may receive the output data signals DR, DG and DB and the data control signal DCS from the display controller 220. The data driver 230 may generate a data signal by using the received output data signals DR, DG and DB and the data control signal DCS. The data driver 230 may provide the generated data signal to the display panel 100. The data driver 230 may provide the data signal to the plurality of pixels PX through a plurality of data lines DL1 to DLn (e.g., DL of FIG. 4) formed in the display panel 100.

In an embodiment, the gate driver 210 may receive the gate control signal GCS from the display controller 220. The gate driver 210 may generate a gate signal by using the received gate control signal GCS. The gate driver 210 may provide the generated gate signal to the display panel 100. The gate driver 210 may provide the gate signal to the plurality of pixels PX through a plurality of gate lines SLI to SLn (e.g., GL of FIG. 4) formed in the display panel 100. A detailed description of the plurality of data lines DLI to DLn and the plurality of gate lines SLI to SLn will be described later with reference to FIG. 4.

In an embodiment, the display driving circuit 200 is shown in FIG. 3 as not including the gate driver 210, but the invention is not limited thereto. For example, in an embodiment, the gate driver 210 may be included in the display driving circuit 200 for controlling the operation of the display panel 100. The gate driver 210, the data driver 230 and the display controller 220 may be formed of an integrated circuit (IC). The gate driver 210 may be formed together with the display panel 100 in a TFT process of the display panel 100. The display controller 220 and the data driver 230 may be merged into each other to configure timing controller embedded driver integrated circuits (TED).

In an embodiment, the display panel 100 may include a plurality of pixels PX connected to a plurality of data lines (DL of FIG. 4) and a plurality of gate lines (GL of FIG. 4).

In an embodiment, a frame frequency for driving the display panel 100 by the display driving circuit 200 may be varied. For example, in an embodiment, the frame frequency may be varied within the range of about 1 Hz to about 240 Hz in accordance with the host or a user's selection. The display driving circuit 200 may be driven at about 60 Hz during one period, and may change the frame frequency to about 120 Hz during another period in accordance with the user's needs.

In an embodiment, a touch sensing area TSA may include a plurality of first electrodes (TE of FIG. 5), a plurality of second electrodes (RE of FIG. 5), a plurality of touch driving lines (TL of FIG. 5) and a plurality of touch sensing lines (RL of FIG. 5). The touch sensing area TSA may sense a touch input by receiving an electrical signal Tx from the touch driving circuit 400 disposed on the circuit board 300 through the plurality of touch driving lines TL or by sending an electrical signal Rx sensed from the plurality of second electrodes RE to the touch driving circuit 400 through the plurality of touch sensing lines RL. In detail, the touch driving circuit 400 may sense a touch input by converting an analog type electrical signal Rx sensed in the touch sensing area TSA into a digital signal. A detailed description of the touch driving circuit 400 will be described later with reference to FIG. 5.

In an embodiment and referring to FIG. 4, the display unit DU may include a display area DA and a non-display area NDA. The display unit DU may include a plurality of subpixels PX, a plurality of gate lines GL and a plurality of data lines DL, which are connected to the plurality of subpixels PX.

In an embodiment, the plurality of gate lines GL may supply the gate signal received from the gate driver 210 to the plurality of subpixels PX. The plurality of gate lines GL may extend in the first direction X, and may be spaced apart from each other in the second direction Y crossing the first direction X.

In an embodiment, the plurality of data lines DL may supply the output data signals DR, DG and DB and the data signals, which are received from the display driving circuit 200, to the plurality of subpixels PX. The plurality of data lines DL may extend in the second direction Y, and may be spaced apart from each other in the first direction X.

In an embodiment, the non-display area NDA may surround the display area DA. For example, the non-display area NDA may include a gate driver 210 for applying gate signals to the plurality of gate lines GL, fan-out lines FOL for connecting the plurality of data lines DL with the display driving circuit 200, and a display pad DP connected to the circuit board 300.

In an embodiment, the display driving circuit 200 may supply the gate control signal GCS to the gate driver 210 through a gate control line GCL. The gate driver 210 may generate a plurality of gate signals based on the gate control signal GCS and sequentially supply the plurality of gate signals to the plurality of gate lines GL in accordance with a set order.

In an embodiment, the display driving circuit 200 may supply a first power voltage to first power lines VL through the data driver 230 and supply a second power voltage to a second power line (not shown). Each of the plurality of subpixels PX may be supplied with the first power voltage through the first power line VL, and may be supplied with the second power voltage through the second power line. The first power voltage may be a predetermined high-level voltage, and the second power voltage may be a voltage lower than the first power voltage.

In an embodiment, a display pad area DPA and a touch peripheral area TPA may be disposed at an edge of the display panel 100. The display pad area DPA may include a plurality of display pads DP. The plurality of display pads DP may be connected to a main processor (not shown) through the circuit board 300. The plurality of display pads DP may be connected to the circuit board 300 to receive digital video data, and may supply the digital video data to the display driving circuit 200.

FIG. 5 is a plan view illustrating a touch unit of a display device, according to an embodiment.

In an embodiment and referring to FIG. 5, the touch unit TSU may include a touch sensing area TSA for sensing a user's touch and a touch peripheral area TPA disposed near the touch sensing area TSA. The touch sensing area TSA may overlap the display area DA of the display panel 100, and the touch peripheral area TPA may overlap the non-display area NDA of the display panel 100.

In an embodiment, the touch unit TSU may include a plurality of first electrodes TE, a plurality of second electrodes RE, a plurality of touch driving lines TL and a plurality of touch sensing lines RL.

In an embodiment, the circuit board 300 may include first circuit pad portions DCPD connected to the display pads DP of the display panel 100, second circuit pad portions TCPD connected to touch pads TP of the display panel 100, and touch circuit lines 212 for connecting the second circuit pad portions TCPD with the touch driving circuit 400.

In an embodiment, the touch sensing area TSA is a touch electrode SEN, and includes a plurality of first electrodes TE and a plurality of second electrodes RE. The plurality of first electrodes TE and the plurality of second electrodes RE may be electrically connected to the touch driving circuit 400 of the circuit board 300. The touch sensing area TSA may receive an electrical signal from the touch driving circuit 400 disposed on the circuit board 300 through the plurality of touch driving lines TL and the plurality of touch sensing lines RL or send the electrical signal sensed from the plurality of first and second electrodes TE and RE to the touch driving circuit 400 through the plurality of touch driving lines TL and the plurality of touch sensing lines RL.

In an embodiment, the plurality of first electrodes TE may be arranged in the first direction X and the second direction Y. The plurality of first electrodes TE may be spaced apart from each other in the first direction X and the second direction Y. The first electrodes TE disposed adjacent to each other in the second direction Y may be electrically connected to each other through a bridge electrode CE.

In an embodiment, the plurality of first electrodes TE may be connected to the touch pad TP through the touch driving line TL. A portion of the plurality of touch driving lines TL may be extended to the touch pad TP after passing through a lower side of the touch peripheral area TPA. Another portion of the plurality of touch driving lines TL may be extended to the touch pad TP via an upper side, a left side and the lower side of the touch peripheral area TPA. The touch pad TP may be connected to the touch driving circuit 400 through the circuit board 300.

In an embodiment, the display pad area DPA and the touch peripheral area TPA may be disposed at an edge of the sub-area SBA of the display panel 100. The display pad area DPA and the touch peripheral area TPA may be electrically connected to the circuit board 300 by using a low-resistance and high-reliability material such as an anisotropic conductive film.

In an embodiment, the plurality of second electrodes RE may be extended in the first direction X, and may be spaced apart from each other in the second direction Y. The plurality of second electrodes RE may be arranged in the first direction X and the second direction Y, and the plurality of second electrodes RE disposed adjacent to each other in the first direction X may be electrically connected to each other through a connection portion.

In an embodiment, the plurality of second electrodes RE may be connected to the touch pad TP through the plurality of touch sensing lines RL. For example, the plurality of second electrodes RE disposed at a right side of the touch sensing area TSA may be connected to the touch pad TP through the plurality of touch sensing lines RL. The plurality of touch sensing lines RL may be extended to the touch pad TP via a right side and a lower side of the touch peripheral area TPA. The touch pad TP may be connected to the touch driving circuit 400 through the circuit board 300.

In an embodiment, the plurality of first electrodes TE and the plurality of second electrodes RE may include a planar pattern made of a transparent conductive layer, or a mesh type pattern to which an opaque metal is applied along an area where a light emitting element is not disposed, so as not to disturb the progress of light emitted from the display area DA.

In an embodiment, a touch driving signal may be applied from the touch driving circuit 400 to each of the plurality of first electrodes TE through any one of the plurality of touch driving lines TL. When the touch driving signal is applied to the plurality of first electrodes TE, mutual capacitance may be formed between the first electrode TE and the second electrode RE, which are disposed adjacent to each other. When a touch input is generated from the outside, a mutual capacitance value between the first electrode TE and the second electrode RE, which are disposed adjacent to each other, may be changed. The change in mutual capacitance value between the first electrode TE and the second electrode RE, which are disposed adjacent to each other, may be transferred to the touch driving circuit 400 through the plurality of touch sensing lines RL. Therefore, the touch driving circuit 400 may determine whether a touch is input and calculate the corresponding position as touch input coordinates. The touch sensing may be performed in a mutual capacitance manner, but is not limited thereto.

In an embodiment, a reference numeral GND, which is not described in FIG. 5, may be a ground line formed in the circuit board 300.

In an embodiment, a reference numeral DME, which is not described in FIG. 5, may be a dummy electrode. The plurality of first electrodes TE, the plurality of second electrodes RE and the plurality of dummy electrodes DME may be disposed on the same layer, and may be spaced apart from one another.

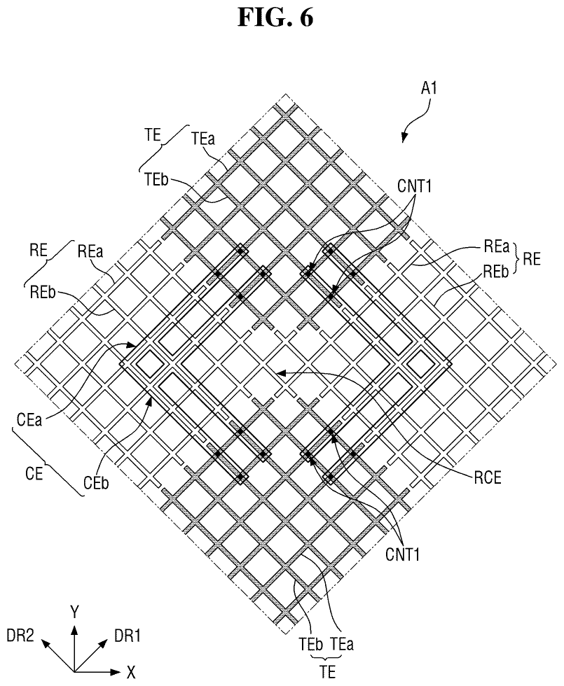

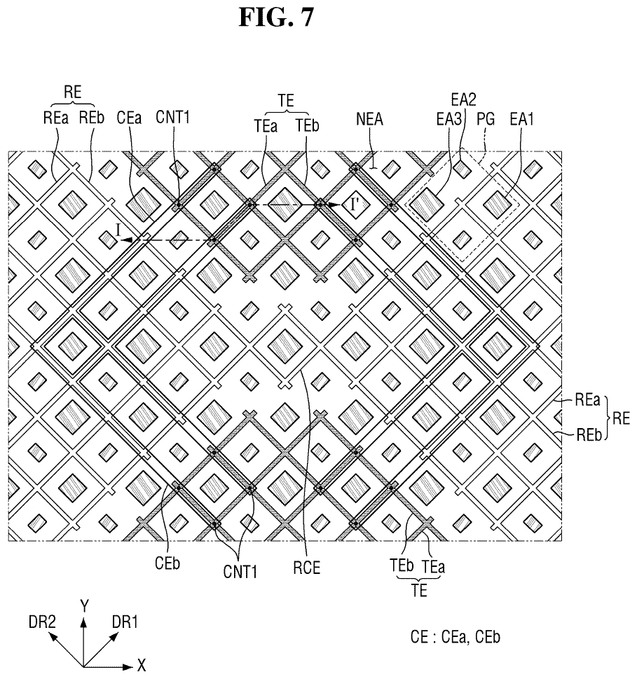

FIG. 6 is an enlarged view of area A1 of FIG. 5, according to an embodiment. FIG. 7 is an enlarged view of a portion of a display device, according to an embodiment.

In an embodiment and referring to FIGS. 6 and 7, the plurality of first electrodes TE may be arranged in the first direction X and the second direction Y. The plurality of first electrodes TE may be spaced apart from each other in the first direction X and the second direction Y. The first electrodes TE disposed adjacent to each other in the second direction Y may be electrically connected to each other through the bridge electrode CE.

In an embodiment, the plurality of second electrodes RE may be extended in the first direction X, and may be spaced apart from each other in the second direction Y. The plurality of second electrodes RE may be arranged in the first direction X and the second direction Y, and the second electrodes RE disposed adjacent to each other in the first direction X may be electrically connected to each other through a connection portion RCE. For example, the connection portion RCE of the second electrodes RE may be disposed to cross between the first electrodes TE disposed adjacent to each other.

In an embodiment, a plurality of bridge electrodes CE may be disposed on a different layer from the first electrode TE and the second electrode RE. The bridge electrode CE may include a first portion CEa and a second portion CEb. For example, the second portion CEb of the bridge electrode CE may be connected to the first electrode TE disposed at one side through a first contact hole CNT1 and thus may extend in the other direction DR2. The first portion CEa of the bridge electrode CE may be bent from the second portion CEb in an area overlapped with the second electrode RE and thus may extend in one direction DR1, and may be connected to the first electrode TE disposed at the other side through the first contact hole CNT1. The one direction DR1 may be a direction between the first direction X and the second direction Y, and the other direction DR2 may be a direction crossing the one direction DR1. For example, each of the plurality of bridge electrodes CE may connect the first electrodes TE disposed adjacent to each other in the second direction Y.

According to an embodiment, the plurality of first electrodes TE, the plurality of second electrodes RE and the plurality of dummy electrodes (DME of FIG. 5) may be formed in a planar mesh structure or a mesh structure. The plurality of first electrodes TE, the plurality of second electrodes RE and the plurality of dummy electrodes (DME of FIG. 5) may not overlap first to third emission areas EA1, EA2, and EA3, respectfully, of the pixel PX. The plurality of bridge electrodes CE may not overlap the emission areas EA1, EA2, and EA3. Therefore, the display device 10 may prevent luminance of light emitted from the emission areas EA1, EA2, and EA3 from being reduced by the touch unit TSU.

In an embodiment, each of the plurality of first electrodes TE may include a first portion TEa extended in one direction DR1 and a second portion TEb extended in the other direction DR2. Each of the plurality of second electrodes RE may include a first portion REa extended in one direction DR1 and a second portion REb extended in the other direction DR2.

According to another embodiment, the plurality of first electrodes TE, the plurality of second electrodes RE and the plurality of dummy electrodes (DME of FIG. 5) may be formed in an entire surface structure and not a planar mesh structure. In this embodiment, the plurality of first electrodes TE, the plurality of second electrodes RE and the plurality of dummy electrodes (DME of FIG. 5) may include a transparent conductive material having high light transmittance, such as indium tin oxide (ITO) and indium zinc oxide (IZO).

In an embodiment, the plurality of pixels PX may include first to third subpixels, and each of the first to third subpixels may include first to third emission areas EA1, EA2, and EA3, respectively. For example, the first emission area EA1 may emit light of a first color or red light, the second emission area EA2 may emit light of a second color or green light, and the third emission area EA3 may emit light of a third color or blue light, but the invention is not limited thereto.

In an embodiment, one pixel PX may include one first emission area EA1, two second emission areas EA2 and one third emission area EA3 to represent a white gray scale. Therefore, the white gray scale may be expressed by combination of light emitted from one first emission area EA1, light emitted from two second emission areas EA2 and light emitted from one third emission area EA3.

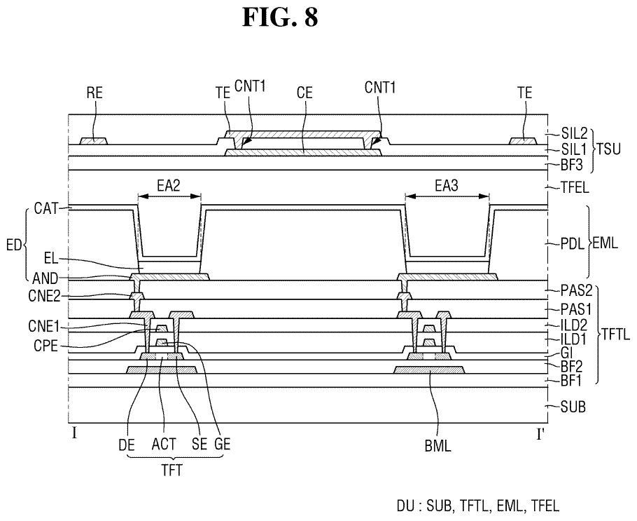

FIG. 8 is a cross-sectional view taken along line I-I′ of FIG. 7, according to an embodiment.

In an embodiment and referring to FIG. 8, the display panel 100 may include a display unit DU and a touch unit TSU. The display unit DU may include a substrate SUB, a thin film transistor layer TFTL, a light emitting element layer EML, and an encapsulation layer TFEL.

In an embodiment, the substrate SUB may support the display panel 100. The substrate SUB may be a base substrate or a base member and may be made of an insulating material such as a polymer resin. For example, in an embodiment, the substrate SUB may be a flexible substrate capable of being subjected to bending, folding, rolling and the like. In another embodiment, the substrate SUB may include a flexible material and a rigid material.

In an embodiment, the thin film transistor layer TFTL may include first and second buffer layers BF1 and BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

In an embodiment, the first buffer layer BF1 may be disposed on the substrate SUB. The first buffer layer BF1 may include an inorganic layer capable of preventing permeation of the air or moisture. In an embodiment, the first buffer layer BF1 may include a plurality of inorganic layers that are alternately stacked.

In an embodiment, a light blocking layer BML may be disposed on the first buffer layer BF1. In an embodiment, the light blocking layer BML may be formed of a single layer or multi-layer made of one of molybdenum (Mo), aluminum (Al), chromium (Cr), gold (Au), titanium (Ti), nickel (Ni), neodymium (Nd) and copper (Cu) or an alloy thereof. In another embodiment, the light blocking layer BML may be an organic layer including a black pigment.

In an embodiment, the second buffer layer BF2 may cover the first buffer layer BF1 and the light blocking layer BML. The second buffer layer BF2 may include an inorganic layer capable of preventing permeation of the air or moisture. In an embodiment, the second buffer layer BF2 may include a plurality of inorganic layers that are alternately stacked.

In an embodiment, the thin film transistor TFT may be disposed on the second buffer layer BF2 and may constitute a pixel circuit of each of the plurality of pixels. In an embodiment, the thin film transistor TFT may be a driving transistor or a switching transistor of the pixel circuit. The thin film transistor TFT may include a semiconductor area ACT, a gate electrode GE, a source electrode SE, and a drain electrode DE.

In an embodiment, the semiconductor area ACT, the source electrode SE and the drain electrode DE may be disposed on the second buffer layer BF2. The semiconductor area ACT may overlap the gate electrode GE in the thickness direction and may be insulated from the gate electrode GE by the gate insulating layer GI. The source electrode SE and the drain electrode DE may be formed by conductorizing a material of the semiconductor area ACT.

In an embodiment, the gate electrode GE may be disposed on the gate insulating layer GI. The gate electrode GE may overlap the semiconductor area ACT with the gate insulating layer GI interposed therebetween.

In an embodiment, the gate insulating layer GI may be disposed on the semiconductor area ACT, the source electrode SE and the drain electrode DE. For example, the gate insulating layer GI may cover the semiconductor area ACT, the source electrode SE, the drain electrode DE and the second buffer layer BF2 and may insulate the semiconductor area ACT from the gate electrode GE. The gate insulating layer GI may include a contact hole through which the first connection electrode CNE1 passes.

In an embodiment, the first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and a contact hole of the second interlayer insulating layer ILD2.

In an embodiment, the capacitor electrode CPE may be disposed on the first interlayer insulating layer ILD1. The capacitor electrode CPE may overlap the gate electrode GE in the third direction (Z-axis direction).

In an embodiment, the second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

In an embodiment, the first connection electrode CNE1 may be disposed on the second interlayer insulating layer ILD2. The first connection electrode CNE1 may connect the drain electrode DE of the thin film transistor TFT with the second connection electrode CNE2. The first connection electrode CNE1 may be inserted into the contact holes formed in the second interlayer insulating layer ILD2, the first interlayer insulating layer ILD1 and the gate insulating layer GI to contact the drain electrode DE of the thin film transistor TFT.

In an embodiment, the first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

In an embodiment, the second connection electrode CNE2 may be disposed on the first passivation layer PAS1. The second connection electrode CNE2 may connect the first connection electrode CNE1 with a first electrode AND of the light emitting element ED. The second connection electrode CNE2 may be inserted into the contact hole provided in the first passivation layer PAS1 to contact the first connection electrode CNE1.

In an embodiment, the second passivation layer PAS2 may cover the second connection electrode CNE2 and the first passivation layer PAS1. The second passivation layer PAS2 may include a contact hole through which the first electrode AND the light emitting element ED passes.

In an embodiment, the light emitting element layer EML may be disposed on the thin film transistor layer TFTL. The light emitting element layer EML may include a light emitting element ED and a pixel defining layer PDL. The light emitting element ED may include a first electrode AND, a light emitting layer EL, and a second electrode CAT.

In an embodiment, the first electrode AND may be disposed on the second passivation layer PAS2. The first electrode AND may be disposed to overlap one of the emission areas EA1, EA2, and EA3 defined by the pixel defining layer PDL. The first electrode AND may be connected to the drain electrode DE of the thin film transistor TFT through the first and second connection electrodes CNE1 and CNE2.

In an embodiment, the light emitting layer EL may be disposed on the first electrode AND. For example, the light emitting layer EL may be an organic light emitting layer made of an organic material, but is not limited thereto. When the light emitting layer EL corresponds to the organic light emitting layer, the thin film transistor TFT may apply a predetermined voltage to the first electrode AND of the light emitting element ED, and when the second electrode CAT of the light emitting element ED receives a common voltage or a cathode voltage, holes and electrons may move to the organic light emitting layer EL through a hole transporting layer and an electron transporting layer, and may be combined with each other in the organic light emitting layer EL to emit light.

In an embodiment, the second electrode CAT may be disposed on the light emitting layer EL. For example, the second electrode CAT may be implemented in the form of an electrode that is not distinguished for each of the plurality of pixels and covers the entire pixels in common. Additionally, the second electrode CAT may be disposed on the light emitting layer EL in the emission areas EA1, EA2, and EA3, and may be disposed on the pixel defining layer PDL in an area excluding the emission areas EA1, EA2, and EA3.

In an embodiment, the pixel defining layer PDL may define the emission areas EA1, EA2, and EA3. The pixel defining layer PDL may separate and insulate the first electrodes AND of the plurality of light emitting elements ED from each other.

In an embodiment, the encapsulation layer TFEL may be disposed on the second electrode CAT to cover the plurality of light emitting elements ED. The encapsulation layer TFEL may include at least one inorganic layer to prevent oxygen or moisture from being permeated into the light emitting element layer EML. The encapsulation layer TFEL may include at least one organic layer to protect the light emitting element layer EML from particles such as dust.

In an embodiment, the touch unit TSU may be disposed on the encapsulation layer TFEL. The touch unit TSU may include a third buffer layer BF3, a bridge electrode CE, a first insulating layer SIL1, a first electrode TE, a second electrode RE and a second insulating layer SIL2.

In an embodiment, the third buffer layer BF3 may be disposed on the encapsulation layer TFEL. The third buffer layer BF3 may have insulating and optical functions. The third buffer layer BF3 may include at least one inorganic layer. In another embodiment, the third buffer layer BF3 may be omitted.

In an embodiment, the bridge electrode CE may be disposed on the third buffer layer BF3. The bridge electrode CE may be disposed on a different layer from the first electrode TE and the second electrode RE to connect the first electrodes TE disposed adjacent to each other in the second direction (e.g., the second direction Y of FIG. 7). For example, the bridge electrode CE may be formed of a single layer of molybdenum (Mo), titanium (Ti), copper (Cu) or aluminum (Al), a stacked structure (Ti/Al/Ti) of aluminum and titanium, a stacked structure (ITO/AI/ITO) of aluminum and ITO, an APC alloy and a stacked structure (ITO/APC/ITO) of an APC alloy and ITO.

In an embodiment, the first insulating layer SILI may cover the bridge electrode CE and the third buffer layer BF3. The first insulating layer SILI may have insulating and optical functions. For example, the first insulating layer SILI may be formed of an inorganic layer, for example, a silicon nitride layer, a silicon oxynitride layer, a silicon oxide layer, a titanium oxide layer or an aluminum oxide layer.

In an embodiment, the first electrode TE and the second electrode RE may be disposed on the first insulating layer SIL1. Each of the first electrode TE and the second electrode RE may not overlap the emission areas EA1, EA2, and EA3. Each of the first electrode TE and the second electrode RE may be formed of a single layer of molybdenum (Mo), titanium (Ti), copper (Cu) and aluminum (Al) or may be formed of a stacked structure (Ti/Al/Ti) of aluminum and titanium, a stacked structure (ITO/Al/ITO) of aluminum and ITO, an APC alloy and a stacked structure (ITO/APC/ITO) of an APC alloy and ITO.

In an embodiment, the second insulating layer SIL2 may cover the first electrode TE, the second electrode RE and the first insulating layer SIL1. The second insulating layer SIL2 may have insulating and optical functions. The second insulating layer SIL2 may be formed of a material exemplified in the first insulating layer SIL1.

In an embodiment and referring to FIG. 8, the bridge electrode CE is formed below the first electrode TE and the second electrode RE, but the invention is not limited thereto. In another embodiment, the bridge electrode CE may be formed on an upper layer of the first electrode TE and the second electrode RE.

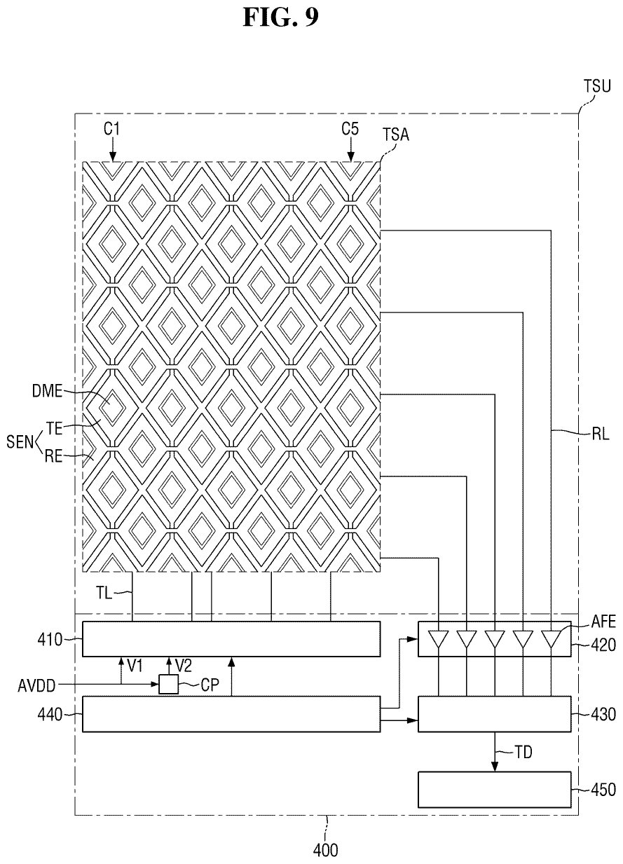

FIG. 9 is a block diagram schematically illustrating compartments of a touch unit and a touch driver, according to an embodiment.

In an embodiment and referring to FIG. 9, the display device 10 may include a touch unit TSU and a touch driving circuit 400. The touch unit TSU shown in FIG. 9 is substantially the same as the touch unit TSU described with reference to FIGS. 2 to 8. Therefore, the description of the touch unit TSU of FIG. 9 will be replaced with the description made with reference to FIGS. 2 to 8.

In an embodiment, the touch driving circuit 400 includes a driving signal output unit 410, a sensing circuit unit 420, an analog-to-digital converter 430, a touch controller 440, and a touch data compensator 450. In addition, the touch driving circuit 400 may further include a charge pump CP receiving an analog voltage AVDD from the outside and boosting the input analog voltage.

In an embodiment, the charge pump CP boosts an analog voltage AVDD having a first potential to generate a high potential power source having a second potential greater than the first potential. The high potential power source boosted from the charge pump CP is supplied to the driving signal output unit 410.

In an embodiment, the driving signal output unit 410 outputs touch driving signals to the first electrodes TE through touch driving lines TL. The touch driving signals may be a plurality of pulse type signals.

In an embodiment, the driving signal output unit 410 may output the touch driving signals to touch driving lines TL in a predetermined order. For example, in an embodiment, the driving signal output unit 410 may sequentially output the touch driving signals from the first electrodes TE of a first column C1 disposed on the leftmost side of the touch sensing area TSA to the first electrodes TE of a fifth column C5 disposed at the rightmost side of the touch sensing area TSA.

In an embodiment, the driving signal output unit 410 may output a first touch driving signal having a first potential V1 or output a second touch driving signal having a second potential V2. According to an embodiment, the touch driving circuit 400 may be controlled by the display driving circuit 200. The driving signal output unit 410 of the touch driving circuit 400 may output the first touch driving signal or the second touch driving signal based on the control of the display driving circuit 200. The first touch driving signal may be a pulse type signal including a first potential V1. The second touch driving signal may be a pulse type signal including a second potential V2 greater than the first potential V1.

According to an embodiment, the first potential V1 is substantially equal to the potential of an externally input analog voltage AVDD. The first potential V1 may be about 3V, but the invention is not limited thereto. The second potential V2 is a high potential power source boosted by the charge pump CP and may be about 6V, but the invention is not limited thereto.

In an embodiment, the sensing circuit unit 420 may be connected to the second electrodes RE via the sensing lines RL. The sensing circuit unit 420 may sense the amount of a charge change in mutual capacitance of touch nodes corresponding to intersections of the first electrodes TE and the second electrodes RE through the sensing lines RL. The sensing circuit unit 420 may acquire raw data corresponding to the amount of the charge change in mutual capacitance of the touch nodes. The raw data may include, for example, first raw data acquired when the driving signal output unit 410 outputs the first touch driving signal and second raw data acquired when the driving signal output unit 410 outputs the second touch driving signal.

In an embodiment, the sensing circuit unit 420 may include operational amplifiers AFE for sensing the amount of the charge change in mutual capacitance of the touch nodes. The operational amplifiers AFE may be connected to the sensing lines RL in a one-to-one correspondence. The operational amplifiers AFE may amplify the raw data input in an analog form.

In an embodiment, the analog-to-digital converter 430 converts each of output voltages of the operational amplifiers AFE of the sensing circuit unit 420 into touch sensing data TD that are digital data.

In an embodiment, the touch controller 440 controls the driving timing of the driving signal output unit 410, the sensing circuit unit 420 and the analog-to-digital converter 430. The touch controller 440 may output a timing signal for synchronizing the driving signal output unit 410, the sensing circuit unit 420 and the analog-to-digital converter 430 to each of the driving signal output unit 410, the sensing circuit unit 420 and the analog-to-digital converter 430.

In addition, in an embodiment, the touch controller 440 may control the driving signal output unit 410 to output a first touch driving signal having a first potential or a second touch driving signal having a second potential based on a control signal of the display driving circuit 200.

In an embodiment, the touch data compensator 450 receives touch sensing data TD sensed from all touch nodes of the touch sensing area TSA from the analog-to-digital converter 430. The touch data compensator 450 calculates a touch area ratio by analyzing the touch sensing data TD and compensates for the touch sensing data TD in accordance with the touch area ratio.

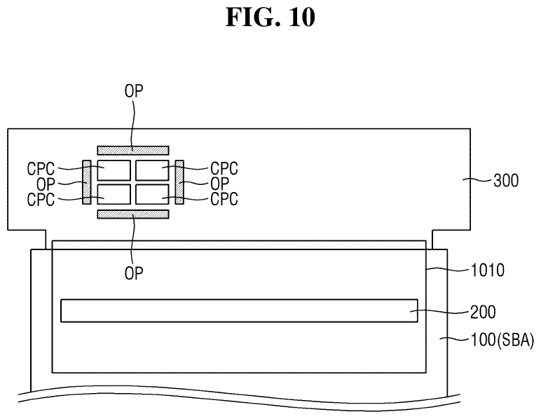

FIG. 10 is a diagram schematically illustrating a connection portion of a circuit board and a display panel, according to an embodiment.

In an embodiment and referring to FIG. 10, the display panel 100 of the display device 10 may include a main area MA including a display area DA and a non-display area NDA and a sub-area SBA extending from one side of the main area MA.

According to an embodiment, the sub-area SBA of the display panel 100 is connected to the circuit board 300. The circuit board 300 is connected to the sub-area SBA of the display panel 100 and a charge pump capacitor CPC is disposed on the surface of the circuit board 300. The charge pump capacitor CPC may refer to a capacitor connected to a charge pump CP described with reference to FIG. 9.

According to an embodiment, at the periphery of the charge pump capacitor CPC, a first cover layer 1110 of the circuit board 300 is removed and an opening OP exposing a ground line GND placed below a first cover layer 1110 is disposed. Accordingly, the ground line GND exposed through the opening OP is disposed at the periphery of the charge pump capacitor CPC. Such opening OP serves as a path for discharging static electricity generated around the charge pump capacitor CPC.

According to an embodiment, the openings OP are disposed to surround the charge pump capacitor CPC. For example, the plurality of openings OP may be disposed at the periphery of the charge pump capacitor CPC, and the plurality of openings OP may be disposed to surround the outer periphery of the charge pump capacitor CPC.

According to an embodiment, each of the openings OP may have a quadrangle shape when viewed from the top. However, the shape of the opening OP is not limited to a quadrangle shape. In addition, when the plurality of openings OP is disposed in the circuit board 300, the area of each of the plurality of openings OP may be different.

In an embodiment, FIG. 10 shows an insulating tape 1010 covering the display driving circuit 200 disposed on the sub-area SBA of the display panel 100.

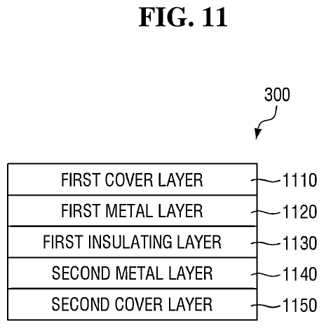

FIG. 11 is a cross-sectional view of a circuit board 300, according to an embodiment. For example, FIG. 11 may be a diagram schematically illustrating a cross-sectional structure of a circuit board 300 explained with reference to FIG. 10.

In an embodiment and referring to FIG. 11, the circuit board 300 may be a flexible printed circuit board. A stacked structure of such circuit board 300 includes a first cover layer 1110, a ground line GND disposed below the first cover layer 1110, a first metal layer 1120 disposed below the first cover layer 1110 and including the ground line GND, a first insulating layer 1130 disposed below the first metal layer 1120, a second metal layer 1140 disposed below the first insulating layer 1130, and a second cover layer 1150 disposed below the second metal layer 1140.

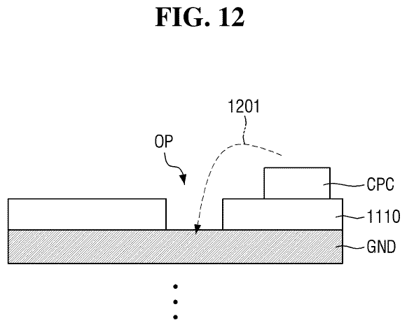

FIG. 12 is a cross-sectional view of a portion of a circuit board 300 showing an opening OP of a first cover layer 1110, according to an embodiment.

In an embodiment and referring to FIG. 12, the opening OP of the circuit board 300 exposes the ground line GND among a plurality of signal lines or a plurality of power lines disposed in the first metal layer. Such opening OP may serve as a path for discharging static electricity generated around the charge pump capacitor CPC, as shown by an arrow 1201 of FIG. 12. For example, static electricity generated around the charge pump capacitor CPC may be discharged to the ground line GND of the circuit board 300 through the opening OP.

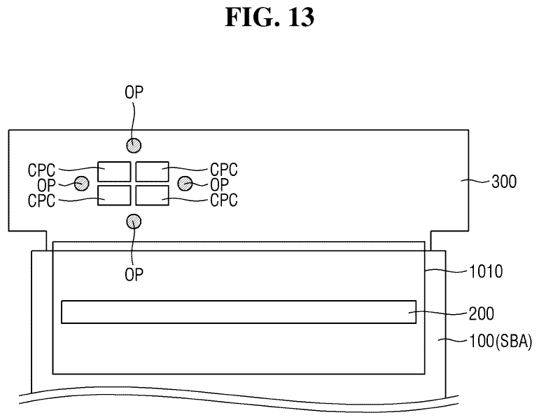

FIG. 13 is a diagram schematically illustrating a connection portion of a circuit board 300 and a display panel 100, according to an embodiment.

Unlike the embodiment of FIG. 10, the embodiment of FIG. 13 is different in that the opening OP has a circular shape when viewed from the top. For example, as illustrated in FIG. 13, each of the opening OP has a circular shape when viewed from the top. However, the shape of the opening OP is not limited to a circular shape. In addition, when the plurality of openings OP is disposed in the circuit board 300, the area and the diameter of each of the plurality of openings OP may be different.

FIG. 13 shows an insulating tape 1010 covering the display driving circuit 200 disposed on the sub-area SBA of the display panel 100.

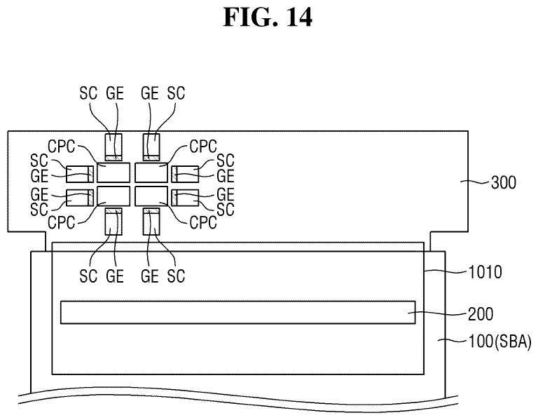

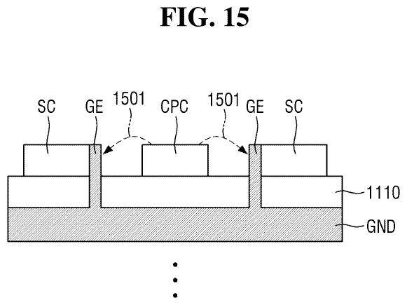

FIG. 14 is a plan view of a circuit board 300 for explaining an arrangement of a stabilization capacitor SC and a charge pump capacitor CPC, according to an embodiment. FIG. 15 is a cross-sectional view of a portion of a circuit board 300 illustrating a ground electrode GE of the stabilization capacitor SC, according to an embodiment.

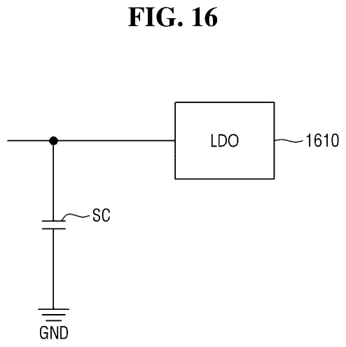

In an embodiment and referring to FIGS. 14 and 15, the circuit board 300 includes the stabilization capacitor SC connected between a regulator element 1610 (see FIG. 16) and the ground line GND.

In an embodiment, the stabilization capacitor SC is connected to the ground line GND and includes a ground electrode GE disposed to face the charge pump capacitor CPC. In an embodiment, the ground electrode GE may be disposed on one side of the stabilization capacitor SC and may be connected to the ground line GND of the circuit board 300 passing through the first cover layer 1110. Here, one side of the stabilization capacitor SC on which the ground electrode GE is disposed may be disposed to face the charge pump capacitor CPC. Such ground electrode GE of the stabilization capacitor SC may serve as a path to discharge static electricity generated around the charge pump capacitor CPC, as shown by arrow 1501 of FIG. 15.

According to an embodiment, the stabilization capacitor SC and the charge pump capacitor CPC are disposed within a specified distance. For example, the stabilization capacitor SC is arranged to surround the charge pump capacitor CPC. In an embodiment, a plurality of stabilization capacitors SC may be disposed at the periphery of the charge pump capacitor CPC, and the ground electrode GE of each of the plurality of stabilization capacitors SC may be disposed to face the charge pump capacitor CPC.

According to an embodiment, the regulator element 1610 may be a low dropout (LDO).

In an embodiment, FIG. 14 shows an insulating tape 1010 covering the display driving circuit 200 disposed on the sub-area SBA of the display panel 100.

FIG. 16 is an equivalent circuit diagram of a stabilization capacitor SC, according to an embodiment.

In an embodiment and referring to FIG. 16, the stabilization capacitor SC may be a component disposed on the surface of the circuit board 300 and may be disposed adjacent to the charge pump capacitor CPC. Such stabilization capacitor SC is connected between the regulator element 1610 (e.g., low dropout (LDO)) and the ground line GND.

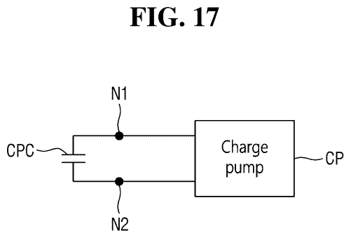

FIG. 17 is an equivalent circuit diagram of a charge pump capacitor CPC, according to an embodiment.

In an embodiment and referring to FIG. 17, the charge pump capacitor CPC is a component disposed on the surface of the circuit board 300 and may be connected in parallel with a charge pump CP. In an embodiment, the charge pump capacitor CPC may be disposed between a first node N1 connected to a boosting portion (e.g., a boosting circuit) of the charge pump CP and a second node N2 connected to a step down portion (e.g., a step down circuit) of the charge pump CP. Since such charge pump capacitor CPC is not connected to the ground in a circuit, the charge pump capacitor CPC may be relatively vulnerable to static electricity compared to the stabilization capacitor SC.

In an embodiment, the opening OP of the circuit board 300 exposing the ground line GND is disposed at the periphery of the charge pump capacitor CPC, which is relatively vulnerable to static electricity, thereby efficiently discharging static electricity generated around the charge pump capacitor CPC.

In addition, in an embodiment, the stabilization capacitor SC is disposed around the charge pump capacitor CPC, which is relatively vulnerable to static electricity, and the ground electrode GE of the stabilization capacitor SC is disposed to face the charge pump capacitor CPC, thereby efficiently discharging static electricity generated around the charge pump capacitor CPC.

In concluding the detailed description, those skilled in the art will appreciate that many variations and modifications can be made to embodiments without substantially departing from the principles of the present invention. Therefore, the disclosed preferred embodiments of the invention are used in a generic and descriptive sense only and not for purposes of limitation. The invention should not be construed as being limited to the embodiments set forth herein. Rather, these embodiments are provided so that this disclosure will be thorough and complete and will fully convey the invention to those skilled in the art. While the invention has been particularly shown and described with reference to embodiments thereof, it will be understood by those of ordinary skill in the art that various changes in form and details may be made therein without departing from the spirit or scope of the invention. Moreover, the embodiments or parts of the embodiments may be combined in whole or in part without departing from the scope of the invention.

What is claimed is:

1. A display device comprising:
a display panel including a main area and a sub-area, wherein the main area includes a display area and a non-display area, and wherein the sub-area extends from one side of the main area; and
a circuit board connected to the sub-area and including a charge pump capacitor,
wherein, around the charge pump capacitor, a first cover layer of the circuit board is removed and an opening exposing a ground line disposed below the first cover layer is disposed.

2. The display device of claim 1,
wherein a stacked structure of the circuit board comprises:
the first cover layer;
a first metal layer disposed below the first cover layer and including the ground line;
a first insulating layer disposed below the first metal layer;
a second metal layer disposed below the first insulating layer; and
a second cover layer disposed below the second metal layer.

3. The display device of claim 2,
wherein the circuit board is a flexible printed circuit board.

4. The display device of claim 3,
wherein the opening is disposed to surround the charge pump capacitor.

5. The display device of claim 4,
wherein the opening includes a plurality of openings and wherein each of the plurality of openings have a quadrilateral shape when viewed from the top.

6. The display device of claim 4,
wherein the opening includes a plurality of openings and wherein each of the plurality of openings have a circular shape when viewed from the top.

7. The display device of claim 1,
wherein the circuit board includes a stabilization capacitor connected between a regulator element and the ground line, and
wherein the stabilization capacitor is connected to the ground line and includes a ground electrode disposed to face the charge pump capacitor.

8. The display device of claim 7,
wherein the stabilization capacitor and the charge pump capacitor are disposed within a specified distance from each other.

9. The display device of claim 8,
wherein the stabilization capacitor is disposed to surround the charge pump capacitor.

10. The display device of claim 8,
wherein the regulator element is a low dropout (LDO).

11. A mobile electronic device comprising:
a display panel including a main area and a sub-area, wherein the main area includes a display area and a non-display area, and wherein the sub-area extends from one side of the main area; and
a circuit board connected to the sub-area and including a charge pump capacitor,
wherein, around the charge pump capacitor, a first cover layer of the circuit board is removed and an opening exposing a ground line disposed below the first cover layer is disposed.

12. The mobile electronic device of claim 11,
wherein a stacked structure of the circuit board comprises:
the first cover layer;
a first metal layer disposed below the first cover layer and including the ground line;
a first insulating layer disposed below the first metal layer;
a second metal layer disposed below the first insulating layer; and
a second cover layer disposed below the second metal layer.

13. The mobile electronic device of claim 12,
wherein the circuit board is a flexible printed circuit board.

14. The mobile electronic device of claim 13,
wherein the opening is disposed to surround the charge pump capacitor.

15. The mobile electronic device of claim 14,
wherein the opening includes a plurality of openings and wherein each of the plurality of openings have a quadrilateral shape when viewed from the top.

16. The mobile electronic device of claim 14,
wherein the opening includes a plurality of openings and wherein each of the plurality of openings have a circular shape when viewed from the top.

17. The mobile electronic device of claim 11,
wherein the circuit board includes a stabilization capacitor connected between a regulator element and the ground line, and
wherein the stabilization capacitor is connected to the ground line and includes a ground electrode disposed to face the charge pump capacitor.

18. The mobile electronic device of claim 17,
wherein the stabilization capacitor and the charge pump capacitor are disposed within a specified distance from each other.

19. The mobile electronic device of claim 18,
wherein the stabilization capacitor is disposed to surround the charge pump capacitor.

20. The mobile electronic device of claim 19,
wherein the regulator element is a low dropout (LDO).
